(19) United States
(12) Patent Application Publication
(10) Pub. No.: US 2025/0389047 A1
(43) Pub. Date: Dec. 25, 2025

(54) VAPOR PHASE GROWTH APPARATUS

(71) Applicants: Kabushiki Kaisha Toshiba, Kawasaki-shi (JP); Toshiba Electronic Devices & Storage Corporation, Kawasaki-shi (JP)

(72) Inventor: Tsutomu KIYOSAWA, Himeji Hyogo (JP)

(21) Appl. No.: 19/312,948

(22) Filed: Aug. 28, 2025

Related U.S. Application Data
(63) Continuation of application No. PCT/JP2023/046029, filed on Dec. 21, 2023.

(30) Foreign Application Priority Data
Jul. 18, 2023 (JP) 2023-117138

(51) Int. Cl. C30B 25/12; C30B 29/36

(52) U.S. Cl. CPC C30B 25/12; C30B 29/36

(57) ABSTRACT

A vapor phase growth apparatus according to an embodiment has a susceptor on which a wafer is to be placed. The vapor phase growth apparatus has a drive portion for rotating the susceptor. The susceptor has a wafer support portion. The wafer support portion supports the wafer. The wafer support portion has an annular shape. The wafer support portion has a support surface. The support surface supports the wafer from below. The support surface has an inclined surface and a flat portion. The inclined surface is connected to an inner edge of the wafer support portion. The flat portion faces upward. The inclined surface is positioned upward as the inclined surface approaches an outward side of the wafer support portion in a radial direction. The flat portion is connected to an outer end portion of the inclined surface in the radial direction.

### CROSS-REFERENCE TO RELATED APPLICATION

This application is a continuation application which claims the benefit of priority from PCT application No. PCT/JP2023/046029, filed on Dec. 21, 2023 which claims the benefit of priority from Japanese Patent Application No. 2023-117138, filed on Jul. 18, 2023, the entire contents of which are incorporated herein by reference.

### FIELD

Embodiments described herein relate generally to a vapor phase growth apparatus.

### BACKGROUND

In a vapor phase growth apparatus, when a wafer is placed on a susceptor and when a film made of SiC or the like is formed on the front surface of a wafer, there is a probability that wafer misalignment, such as rotational movement of the wafer with respect to the susceptor, will occur. If such wafer misalignment occurs, there is a probability that flatness of a wafer will deteriorate due to formation of a SiC film on the rear surface of the wafer, and that thickness uniformity of a film formed on the front surface of the wafer will deteriorate.

### BRIEF DESCRIPTION OF THE DRAWINGS

FIG. 1 is a cross-sectional view showing a vapor phase growth apparatus according to an embodiment.

FIG. 2 is a cross-sectional view showing a part of the vapor phase growth apparatus according to the embodiment.

FIG. 3 is a top view showing a part of the vapor phase growth apparatus according to the embodiment.

FIG. 4 is a cross-sectional view showing another part of the vapor phase growth apparatus according to the embodiment.

FIG. 5 is an enlarged cross-sectional view showing a part of the vapor phase growth apparatus according to the embodiment.

FIG. 6 is a top view showing a part of a vapor phase growth apparatus according to a first modification example of the embodiment.

FIG. 7 is an enlarged cross-sectional view showing a part of the vapor phase growth apparatus according to the first modification example of the embodiment.

FIG. 8 is a top view showing another part of the vapor phase growth apparatus according to the first modification example of the embodiment.

FIG. 9 is a top view showing a part of a vapor phase growth apparatus according to a second modification example of the embodiment.

### DETAILED DESCRIPTION

A vapor phase growth apparatus according to an embodiment has a susceptor on which a wafer is to be placed. The vapor phase growth apparatus has a drive portion for rotating the susceptor. The susceptor has a wafer support portion. The wafer support portion supports the wafer. The wafer support portion has an annular shape. The wafer support portion has a support surface. The support surface supports the wafer from below. The support surface has an inclined surface and a flat portion. The inclined surface is connected to an inner edge of the wafer support portion. The flat portion faces upward. The inclined surface is positioned upward as the inclined surface approaches an outward side of the wafer support portion in a radial direction. The flat portion is connected to an outer end portion of the inclined surface in the radial direction.

Hereinafter, the susceptor and the vapor phase growth apparatus according to the embodiment will be described with reference to the drawings.

In each of the drawings, a Z axis direction is a vertical direction. A side toward which the arrow in the Z axis direction points (positive Z side) is an upward side in the vertical direction. A side opposite to the side toward which the arrow in the Z axis direction points (negative Z side) is a downward side in the vertical direction. In the following description, the upward side in the vertical direction will be simply referred to as “the upward side”, and the downward side in the vertical direction will be simply referred to as “the downward side”.

A direction in which a rotation axis J shown in each diagram extends is parallel to the Z axis direction. The rotation axis J is a virtual axis. In the following embodiment, the susceptor rotates about the rotation axis J. In the following description, the radial direction about the rotation axis J will be simply referred to as “the radial direction”. In the following embodiment, the radial direction of the wafer support portion is the same direction as the radial direction about the rotation axis J. The radial direction of the wafer support portion and the radial direction about the rotation axis J may be directions different from each other. A circumferential direction about the rotation axis J will be simply referred to as “a circumferential direction”. In each diagram, the circumferential direction is indicated by an arrow θ. In the following embodiment, the circumferential direction of the wafer support portion is the same direction as the circumferential direction about the rotation axis J. The circumferential direction of the wafer support portion and the circumferential direction about the rotation axis J may be directions different from each other.

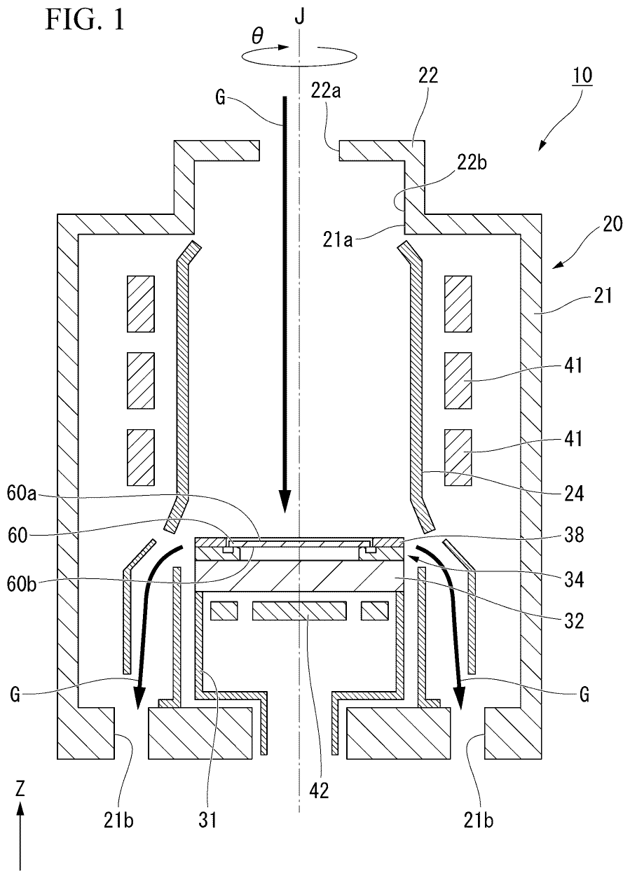

A vapor phase growth apparatus 10 of the present embodiment shown in FIG. 1 is a film formation apparatus that forms an epitaxial film on a front surface 60a, which is a surface of a wafer 60 facing upward, by a chemical vapor deposition (CVD) method. In the present embodiment, a SiC film is formed on the front surface 60a of the wafer 60. The film formed on the front surface 60a of the wafer 60 may be a film constituted using other materials such as Si. The vapor phase growth apparatus 10 includes a chamber 20, a supply pipe 24, a drive portion 31, a susceptor holding portion 32, a susceptor 34, a wafer guide 38, first heating portions 41, and a second heating portion 42.

The chamber 20 accommodates the supply pipe 24, the drive portion 31, the susceptor holding portion 32, the susceptor 34, the wafer guide 38, the first heating portions 41, and the second heating portion 42 therein. The chamber 20 has a main body portion 21 and a supply portion 22. In the present embodiment, the chamber 20 is made of a metal.

The main body portion 21 accommodates the supply pipe 24, the drive portion 31, the susceptor holding portion 32, the susceptor 34, the wafer guide 38, the first heating portions 41, and the second heating portion 42 therein. The main body portion 21 has a tubular shape extending in the vertical direction. The main body portion 21 is provided with a main body portion opening 21a opening upward. The main body portion 21 is provided with a discharge port 21b opening downward. An excess gas G inside the chamber 20 is discharged through the discharge port 21b.

The supply portion 22 is fixed to an upper end of the main body portion 21. The supply portion 22 has a tubular shape protruding in the vertical direction. The supply portion 22 is provided with a supply port 22a opening upward. The supply portion 22 is provided with a supply portion opening 22b opening downward. The inside of the supply portion 22 and the inside of the main body portion 21 are connected through the supply portion opening 22b and the main body portion opening 21a. The gas G supplied to the inside of the supply portion 22 through the supply port 22a is supplied to the inside of the main body portion 21 through the supply portion opening 22b and the main body portion opening 21a.

The supply pipe 24 is accommodated inside the main body portion 21. The supply pipe 24 has a tubular shape extending in the vertical direction. The supply pipe 24 opens both upward and downward. Inside the supply pipe 24, the gas G flows downward. The gas G flowing downward inside the supply pipe 24 is supplied to the wafer 60. The excess gas G inside the supply pipe 24 is discharged to the outside of the vapor phase growth apparatus 10 through the downward opening of the supply pipe 24 and the discharge port 21b. In the present embodiment, the supply pipe 24 is made of graphite. A coating layer made of a material such as SiC or tantalum carbide (TaC) may be provided on a surface of the supply pipe 24.

In the present embodiment, the gas G contains a source gas, an impurity gas, a carrier gas, and hydrogen chloride (HCl) gas. The source gas contains silane (SiH4) and propane (C3H8). The flow rate of the source gas is preferably within a range of several tens of sccm to several hundreds of sccm. The impurity gas contains nitrogen and trimethyl aluminum (TMA). The flow rate of the impurity gas is preferably within a range of several sccm to several hundreds of sccm. The carrier gas is either argon gas or hydrogen gas. More specifically, the carrier gas used when the wafer 60 is carried into the vapor phase growth apparatus 10 and placed on the susceptor 34 and when the wafer 60 after film formation is removed from the susceptor 34 and carried out of the vapor phase growth apparatus 10 is argon gas. In addition, the carrier gas used during film formation is hydrogen gas. The flow rate of the carrier gas is preferably within a range of 100 slm to 200 slm. The flow rate of the hydrogen chloride gas is preferably within a range of several tens of sccm to several slm. The flow rate and the like of each of the source gas, the impurity gas, the carrier gas, and the hydrogen chloride gas are adjusted by a gas adjustment portion (not shown).

The first heating portions 41 have an annular shape surrounding the supply pipe 24. The first heating portions 41 are disposed between the main body portion 21 and the supply pipe 24. In the present embodiment, the vapor phase growth apparatus 10 includes three first heating portions 41. The first heating portions 41 are disposed with an interval therebetween in the vertical direction. Each of the first heating portions 41 heats the gas G passing through the inside of the supply pipe 24. Accordingly, since the temperature of the gas G when it arrives at the wafer 60 can be increased, the film formation rate of the SiC film can be increased. The number of first heating portions 41 included in the vapor phase growth apparatus 10 may be two or smaller or may be four or larger.

The second heating portion 42 is disposed inside the drive portion 31. The second heating portion 42 is disposed below the susceptor holding portion 32. During film formation, the second heating portion 42 heats each of the susceptor holding portion 32, the susceptor 34, and the wafer 60. During film formation, the second heating portion 42 heats the wafer 60 to a temperature of 1,500° C. to 1,650° C. If the gas G is supplied to the front surface 60a of the wafer 60 heated to such a temperature and held for a certain period of time, a SiC film having a desired thickness is formed on the front surface 60a of the wafer 60.

The drive portion 31 includes a drive device, such as a motor (not shown), for example. The drive portion 31 is rotated by the drive device around the rotation axis J. The drive portion 31 is disposed below the susceptor holding portion 32. The drive portion 31 is fixed to the susceptor holding portion 32. The drive portion 31 rotates each of the susceptor holding portion 32, the susceptor 34, the wafer guide 38, and the wafer 60 around the rotation axis J. Thus, according to the present embodiment, during film formation of forming a SiC film on the front surface 60a of the wafer 60, the wafer 60 can be rotated around the rotation axis J by the drive portion 31. For this reason, variation in the amount of the supplied gas G and the concentration of the gas G within the front surface 60a can be reduced. Therefore, thickness uniformity of the film formed on the wafer 60 can be improved.

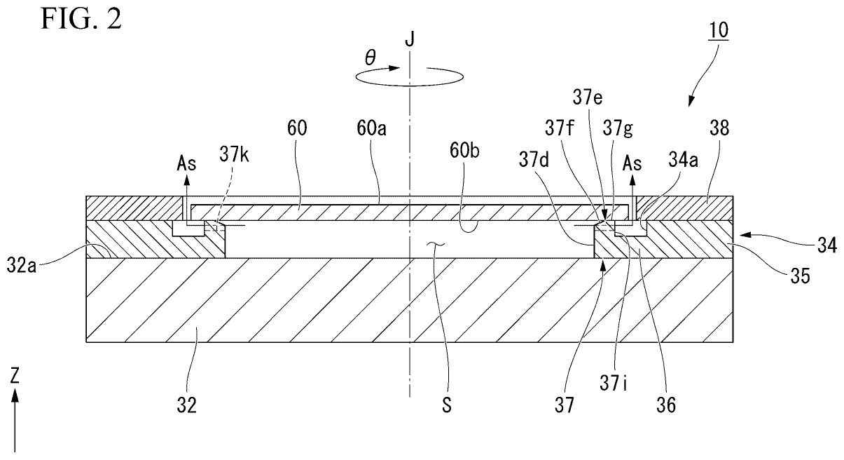

The susceptor holding portion 32 has a plate shape extending in a direction orthogonal to the vertical direction. In the present embodiment, the susceptor holding portion 32 has substantially a disk shape about the rotation axis J. When viewed in the vertical direction, the susceptor holding portion 32 may have a polygonal shape such as a quadrangular shape or other shapes such as an elliptical shape. As described above, the drive portion 31 is fixed to the susceptor holding portion 32. As shown in FIG. 2, the susceptor 34 is fixed to a holding portion front surface 32a that is a surface of the susceptor holding portion 32 facing upward. Accordingly, the susceptor holding portion 32 holds the susceptor 34. In the present embodiment, the susceptor holding portion 32 is made of graphite. A coating layer made of a material such as SiC or TaC may be provided on surface of the susceptor holding portion 32.

The wafer 60 is placed on the susceptor 34. The susceptor 34 supports the wafer 60 from below. In the present embodiment, the susceptor 34 has substantially a toric shape about the rotation axis J. As described above, the susceptor 34 is held by the susceptor holding portion 32. The susceptor 34 rotates around the rotation axis J. The susceptor 34 includes a guide support portion 35, a connection portion 36, and a wafer support portion 37. In the present embodiment, the susceptor 34 is made of graphite. A coating layer made of a material such as SiC or TaC may be provided on surface of the susceptor 34.

The guide support portion 35 has a toric shape about the rotation axis J. The guide support portion 35 is an outward part of the susceptor 34 in the radial direction. A surface of the guide support portion 35 facing downward comes into contact with the susceptor holding portion 32 in the vertical direction.

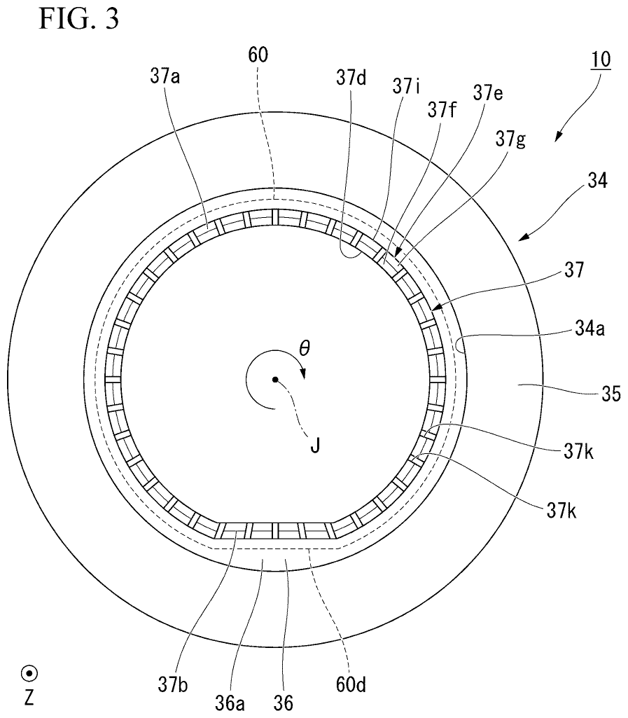

The connection portion 36 protrudes inward in the radial direction from the guide support portion 35. The connection portion 36 has a toric shape about the rotation axis J. A surface of the connection portion 36 facing downward comes into contact with the susceptor holding portion 32 in the vertical direction. The surface of the connection portion 36 facing upward is positioned below a surface of the guide support portion 35 facing upward. As shown in FIG. 3, the connection portion 36 has an exposed portion 36a. The exposed portion 36a is a part on the surface of the connection portion 36 facing upward and is a part overlapping a gap between an orientation flat portion 60d of the wafer 60 (which will be described below) and the guide support portion 35 when viewed in the vertical direction. The exposed portion 36a is exposed upward through the gap between the orientation flat portion 60d and the guide support portion 35. For this reason, during film formation, a SiC laminate is formed on the exposed portion 36a.

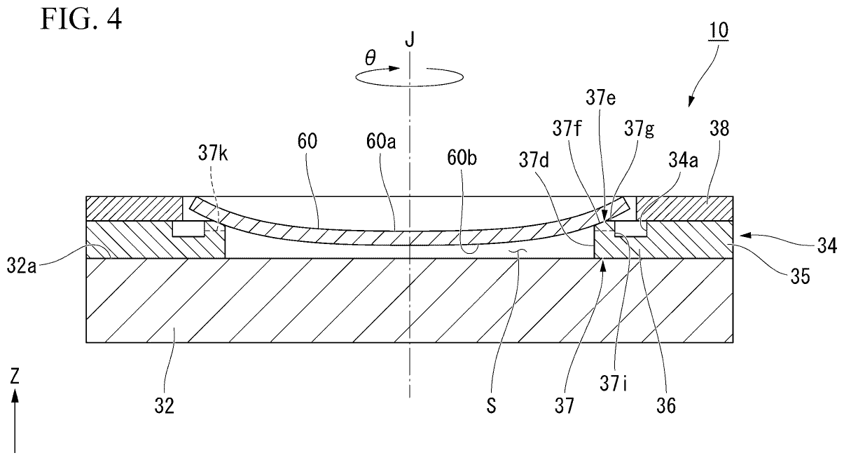

The wafer support portion 37 extends along the circumferential direction. In the present embodiment, the wafer support portion 37 has an annular shape surrounding the rotation axis J. The wafer support portion 37 is disposed inward from the connection portion 36 in the radial direction. The wafer support portion 37 is connected to the connection portion 36. As shown in FIG. 2, an upper end of the wafer support portion 37 is positioned above an upper end of the connection portion 36. The wafer support portion 37 is disposed inward from the wafer guide 38 in the radial direction. The wafer support portion 37 has a support portion inner side surface 37d, a support surface 37e, and a support portion outer side surface 37i. As shown in FIG. 3, the wafer support portion 37 has an arc portion 37a, a straight portion 37b, a plurality of recessed portions 37k. As shown in FIGS. 2 and 4, the wafer 60 is placed on the wafer support portion 37. The wafer support portion 37 supports the wafer 60.

As shown in FIG. 2, the wafer 60 has substantially a disk shape extending in a direction orthogonal to the vertical direction. In the present embodiment, the wafer 60 is constituted using SiC. The material constituting the wafer 60 may be other materials such as Si. As shown in FIG. 3, the linearly extending orientation flat portion 60d is provided in a part of the outer circumference of the wafer 60. The orientation flat portion 60d is formed in the wafer 60 in order to indicate the crystal orientation of the wafer 60.

During film formation, if the wafer 60 is heated by the second heating portion 42, the temperature on a rear surface 60b that is a surface of the wafer 60 facing downward becomes higher than the temperature on the front surface 60a of the wafer 60. Thus, thermal expansion on the rear surface 60b of the wafer 60 becomes greater than thermal expansion on the front surface 60a of the wafer 60. Therefore, as shown in FIG. 4, during film formation, the wafer 60 is thermally deformed into a shape in which its center portion in the radial direction is warped downward.

As shown in FIG. 3, the arc portion 37a is an arc-shaped part of the wafer support portion 37 about the rotation axis J. In the present embodiment, the central angle of the arc portion 37a is approximately 320°. The central angle of the arc portion 37a may be smaller than 320° or may be larger than 320°. The straight portion 37b is a linearly extending part of the wafer support portion 37. Both ends of the straight portion 37b are respectively connected to end portions of the arc portion 37a in the circumferential direction different from each other. An inward part of the orientation flat portion 60d in the radial direction, of an outer edge portion of the wafer 60 in the radial direction, is supported by the straight portion 37b. Parts other than the inward part of the orientation flat portion 60d in the radial direction, of the outer edge portion of the wafer 60 in the radial direction, are supported by the arc portion 37a.

The support portion inner side surface 37d is an inner side surface of the wafer support portion 37. The support portion inner side surface 37d faces inward in the radial direction. The support portion inner side surface 37d is constituted of an inner side surface of the arc portion 37a in the radial direction and an inner side surface of the straight portion 37b in the radial direction. The support portion outer side surface 37i is an outer side surface of the wafer support portion 37. The support portion outer side surface 37i faces outward in the radial direction. The support portion outer side surface 37i is constituted of an outer side surface of the arc portion 37a in the radial direction and an outer side surface of the straight portion 37b in the radial direction.

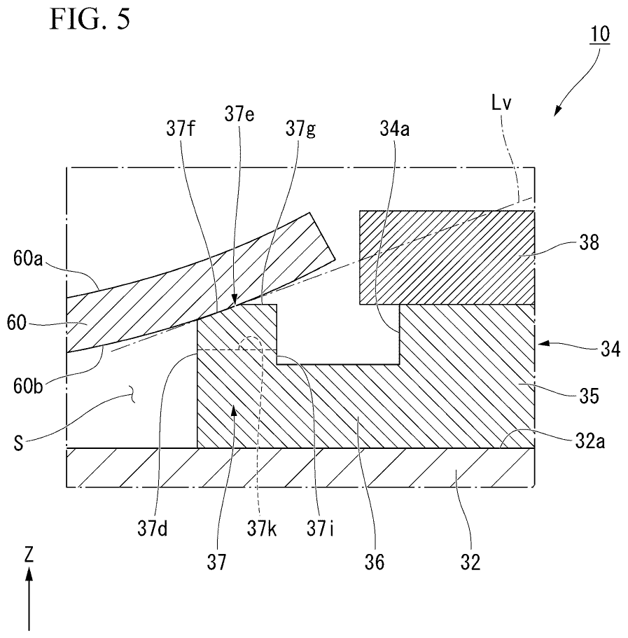

When viewed in the vertical direction, the support surface 37e has an annular shape surrounding the rotation axis J. As shown in FIGS. 2 and 4, the support surface 37e supports the wafer 60 from below. As shown in FIG. 5, the support surface 37e has an inclined surface 37f and a flat portion 37g.

The inclined surface 37f is connected to an upper end portion of the support portion inner side surface 37d. That is, the inclined surface 37f is connected to the inner edge of the wafer support portion 37. The inclined surface 37f is an inclined surface positioned upward as the inclined surface 37f approaches an outward side of the wafer support portion 37 in a radial direction. Thus, according to the present embodiment, as described above, even if the wafer 60 is thermally deformed into a shape of being warped downward during film formation, the rear surface 60b of the wafer 60 and the inclined surface 37f are likely to come into surface contact with each other. For this reason, it is easy to curb decrease in the contact area between the wafer 60 and the wafer support portion 37. Accordingly, a frictional force between the wafer 60 and the wafer support portion 37 can be increased. Therefore, during film formation, even if the susceptor 34 having the wafer 60 placed thereon is rotated, occurrence of wafer misalignment such as rotational movement of the wafer 60 with respect to the susceptor 34 can be curbed. Accordingly, thickness uniformity of the film formed on the wafer 60 can be improved.

In the susceptor 34 having a constitution in which the inclined surface 37f is not provided in the wafer support portion 37, if the wafer 60 is thermally deformed into a shape of being warped downward during film formation, the rear surface 60b of the wafer 60 and a corner portion at the upper end on the support portion inner side surface 37d of the wafer support portion 37 chafe against each other. For this reason, wear powder of the wafer support portion 37 is likely to be generated. If such wear powder enters a gap between the wafer 60 and the support surface 37e, a frictional force between the wafer 60 and the wafer support portion 37 decreases. For this reason, wafer misalignment is likely to occur during film formation. In contrast, in the present embodiment, since the wafer support portion 37 has the inclined surface 37f described above, it is easy to bring the rear surface 60b of the wafer 60 and the inclined surface 37f into surface contact with each other. Accordingly, it is easy to curb a situation in which the rear surface 60b of the wafer 60 and the corner portion of the wafer support portion 37 chafe against each other. Thus, since generation of wear powder of the wafer support portion 37 can be curbed, a frictional force between the wafer 60 and the wafer support portion 37 can be increased. Therefore, occurrence of wafer misalignment can be curbed during film formation.

As described above, in the present embodiment, since occurrence of wafer misalignment during film formation can be curbed, positional misalignment of the orientation flat portion 60d of the wafer 60 with respect to the susceptor 34 during film formation can be curbed. Accordingly, a situation in which the SiC laminate laminated on the exposed portion 36a faces the wafer 60 in the vertical direction can be curbed. Therefore, adhesion of a part of the SiC laminate which has been sublimated by heating to the rear surface 60b of the wafer 60 can be curbed during film formation. For this reason, deterioration in flatness of the rear surface 60b of the wafer 60 can be curbed. Accordingly, deterioration in flatness of the wafer 60 can be curbed. In addition, when the dimension of the SiC laminate laminated on the exposed portion 36a in the vertical direction is large, a situation in which the wafer 60 runs onto such a SiC deposit can be curbed. Therefore, since inclination of the wafer 60 can be curbed during film formation, thickness uniformity of the film formed on the wafer 60 can be improved.

As shown in FIG. 3, the inclined surface 37f extends along the circumferential direction of the wafer support portion 37. The inclined surface 37f has an annular shape surrounding the rotation axis J. In the present embodiment, the inclined surface 37f is divided into a plurality of parts by the plurality of recessed portions 37k. The inclined surface 37f is provided across the arc portion 37a and the straight portion 37b. Thus, according to the present embodiment, during film formation, the rear surface 60b of the wafer 60 and the inclined surface 37f can be brought into contact with each other in the circumferential direction. Accordingly, since the contact area between the rear surface 60b of the wafer 60 and the inclined surface 37f can be increased, a frictional force between the wafer 60 and the wafer support portion 37 can be more favorably increased. Therefore, since occurrence of wafer misalignment can be more favorably curbed during film formation, formation of a SiC film on the rear surface 60b of the wafer 60 can be curbed. Therefore, deterioration in flatness of the wafer 60 can be curbed. In addition, thickness uniformity of the film formed on the wafer 60 can be more favorably improved.

As shown in FIG. 5, the flat portion 37g is a surface, of external surfaces of the wafer support portion 37, facing upward. The flat portion 37g extends in a direction orthogonal to the vertical direction. The flat portion 37g is connected to both the outer end portion of the inclined surface 37f in the radial direction and the upper end of the support portion outer side surface 37i. Thus, according to the present embodiment, as shown in FIG. 2, when the wafer 60 is placed on the susceptor 34, rear surface 60b of the wafer 60 and the flat portion 37g can be brought into surface contact with each other. Accordingly, a frictional force between the wafer 60 and the wafer support portion 37 can be increased. Therefore, during placement, occurrence of wafer misalignment such as rotational movement of the wafer 60 with respect to the susceptor 34 can be curbed. As shown in FIG. 3, the flat portion 37g extends along the circumferential direction of the wafer support portion 37. The flat portion 37g has an annular shape surrounding the rotation axis J. In the present embodiment, the flat portion 37g is divided into a plurality of parts by the plurality of recessed portions 37k.

The susceptor 34 has a susceptor groove portion 34a. The susceptor groove portion 34a is a groove recessed downward from a surface of the susceptor 34 facing upward. The susceptor groove portion 34a is constituted of the inner side surface of the guide support portion 35, the surface of the connection portion 36 facing upward, and the support portion outer side surface 37i. As shown in FIG. 3, when viewed in the vertical direction, the susceptor groove portion 34a has an annular shape surrounding the rotation axis J.

Each of the plurality of recessed portions 37k is a recess recessed downward from the support surface 37e. The plurality of recessed portions 37k are disposed with an interval therebetween along the circumferential direction of the wafer support portion 37. In the present embodiment, each of the recessed portions 37k is a groove extending in the radial direction. As shown in FIG. 5, in the present embodiment, each of the recessed portions 37k is provided across the inclined surface 37f and the flat portion 37g. Thus, as shown in FIG. 2, if the wafer 60 is placed on the susceptor 34, the rear surface 60b of the wafer 60 comes into contact with a part of the corner portion at the upper end of each of the recessed portions 37k positioned in the flat portion 37g, that is, an outward part of the corner portion at the upper end of each of the recessed portions 37k in the radial direction. In addition, as shown in FIG. 4, during film formation, the rear surface 60b of the wafer 60 comes into contact with a part of the corner portion at the upper end of each of the recessed portions 37k positioned on the inclined surface 37f, that is, an inward part of the corner portion at the upper end of each of the recessed portions 37k in the radial direction. Thus, according to the present embodiment, during each of placement and film formation, if the wafer 60 tends to rotationally move with respect to the susceptor 34, the rear surface 60b of the wafer 60 is caught by the corner portion at the upper end of each of the recessed portions 37k. Accordingly, a frictional force between the wafer 60 and the wafer support portion 37 can be increased. Therefore, during each of placement and film formation, occurrence of wafer misalignment can be more favorably curbed. Accordingly, since formation of a SiC film on the rear surface 60b of the wafer 60 can be curbed, deterioration in flatness of the wafer 60 can be more favorably curbed, and thickness uniformity of the film formed on the wafer 60 can be more favorably improved.

As shown in FIG. 3, in the present embodiment, the wafer support portion 37 has 36 recessed portions 37k. The number of recessed portions 37k included in the wafer support portion 37 may be 35 or smaller or may be 37 or larger. In the present embodiment, each of the recessed portions 37k opens on each of the support portion inner side surface 37d, that is, the inner side surface of the wafer support portion 37, and the support portion outer side surface 37i, that is, the outer side surface of the wafer support portion 37. Thus, according to the present embodiment, as shown in FIG. 2, during placement of placing the wafer 60 on the susceptor 34, a gas As in a lower space S that is a space surrounded by the wafer 60, the susceptor 34, and the susceptor holding portion 32 can be discharged to the outside of the susceptor 34 through each of the recessed portions 37k. Accordingly, during placement, the wafer 60 can be stably supported by the support surface 37e of the wafer support portion 37. Therefore, when the wafer 60 is placed on the susceptor 34, occurrence of wafer misalignment can be curbed. For this reason, deterioration in flatness of the wafer 60 can be more favorably curbed, and thickness uniformity of the film formed on the wafer 60 can be more favorably improved.

In addition, according to the present embodiment, during film formation, even if the temperature of the gas As in the lower space S rises and the volume of the gas As increases, such a gas As can be discharged to the outside of the susceptor 34 through each of the recessed portions 37k. Accordingly, during film formation, the wafer 60 can be stably supported by the support surface 37e. Therefore, even if the susceptor 34 is rotated, occurrence of wafer misalignment can be curbed during film formation. Therefore, deterioration in flatness of the wafer 60 can be more favorably curbed, and uniformity of the film formed on the wafer can be more favorably improved.

As shown in FIGS. 2 and 4, the wafer guide 38 has an annular shape surrounding the rotation axis J. In the present embodiment, the wafer guide 38 has a toric shape about the rotation axis J. In the present embodiment, the wafer guide 38 is made of poly-SiC. The wafer guide 38 may be made of graphite. In this case, a coating layer constituted using SiC may be provided on surface of the wafer guide 38. The coating layer constituted using SiC may be provided only on the front surface and the side surface and not on the rear surface of the wafer guide 38. In the present embodiment, the wafer guide 38 and the susceptor 34 are members different from each other. Each of the wafer guide 38 and the susceptor 34 may be integrally molded. The wafer guide 38 is supported from below by the guide support portion 35 of the susceptor 34. The wafer guide 38 is supported by the guide support portion 35. The wafer guide 38 surrounds an outer edge of the wafer 60 disposed on the susceptor 34 from the outward side in the radial direction. During film formation, a part on an inner side surface of the wafer guide 38 comes into contact with the wafer 60, which rotates around the rotation axis J, in the radial direction, thereby curbing a situation in which the wafer 60 jumps out to the outward side of the wafer guide 38. The wear powder of the wafer guide 38 generated by the inner side surface of the wafer guide 38 and the wafer 60 chafing against each other is accommodated inside the susceptor groove portion 34a. Therefore, since entry of such wear powder to the gap between the wafer 60 and the support surface 37e can be curbed, decrease in the frictional force between the wafer 60 and the wafer support portion 37 can be curbed. Therefore, occurrence of wafer misalignment can be curbed during film formation.

A virtual straight line Lv shown in FIG. 5 is a virtual straight line passing through an inner end portion of the inclined surface 37f in the radial direction and the outer end portion of the inclined surface 37f in the radial direction. The virtual straight line Lv intersects the inner side surface facing the inward side of the wafer guide 38 in the radial direction. Since a centrifugal force is applied to the wafer 60 which rotates around the rotation axis J during film formation, the wafer 60 tends to move outward in the radial direction. In addition, as described above, during film formation, the wafer 60 is thermally deformed into a shape in which its center portion in the radial direction is warped downward, the rear surface 60b of the wafer 60 comes into surface contact with the inclined surface 37f. Therefore, during film formation, the wafer 60 tends to move in a direction along the virtual straight line Lv. In contrast, according to the present embodiment, as described above, the virtual straight line Lv intersects the inner side surface facing the inward side of the wafer guide 38 in the radial direction. Thus, the inner side surface of the wafer guide 38 can be disposed in a direction in which the wafer 60 tends to move. Therefore, since movement of the wafer 60 can be curbed by the inner side surface of the wafer guide 38, a situation in which the wafer 60 jumps out to the outward side of the wafer guide 38 can be curbed.

In the present embodiment, the wafer support portion 37 does not have to have either the inclined surface 37f or the plurality of recessed portions 37k. If the wafer support portion 37 has either the inclined surface 37f or the plurality of recessed portions 37k, as described above, a frictional force between the rear surface 60b of the wafer 60 and the wafer support portion 37 can be increased. Therefore, during placement and film formation, occurrence of wafer misalignment can be curbed.

### First Modification Example

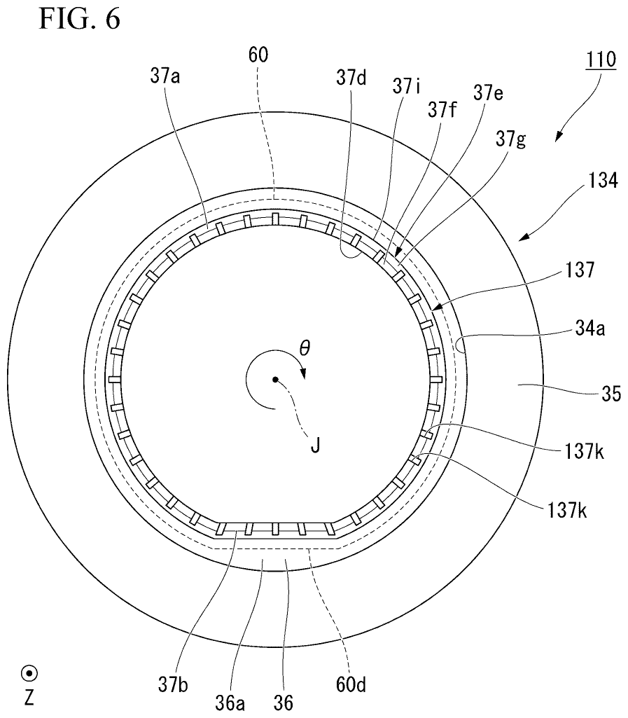

FIG. 6 is a top view showing a part of a vapor phase growth apparatus 110 according to the present modification example. In the following description, the same reference signs will be applied to constituent elements having the same form as those of the embodiment described above, and description thereof may be omitted.

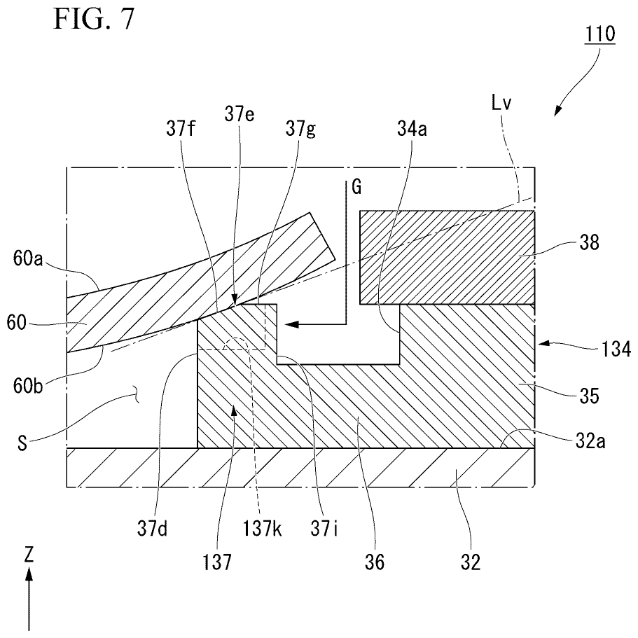

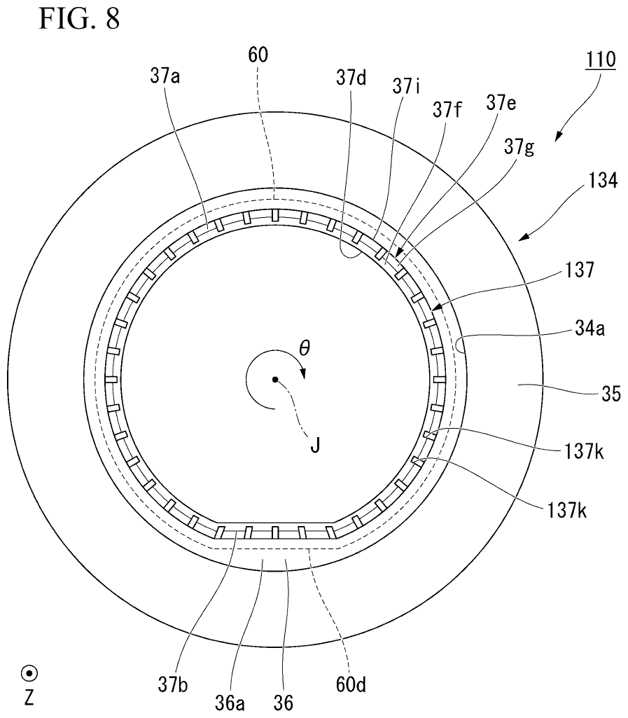

In the present modification example, as shown in FIG. 6, each of a plurality of recessed portions 137k provided in a wafer support portion 137 opens on the support portion inner side surface 37d. Each of the recessed portions 137k does not open on the support portion outer side surface 37i. That is, each of the plurality of recessed portions 137k opens only on either the support portion inner side surface 37d, that is, the inner side surface of the wafer support portion 137 or the support portion outer side surface 37i, that is, the outer side surface of the wafer support portion 137. As shown in FIG. 8, each of the plurality of recessed portions 137k may open on the support portion outer side surface 37i. In this case, each of the recessed portions 137k does not open on the support portion inner side surface 37d. Thus, according to the present modification example, as shown in FIG. 7, during film formation, inflow of the gas G into the lower space S that is a space surrounded by the wafer 60, a susceptor 134, and the susceptor holding portion 32 through each of the recessed portions 137k can be curbed. Accordingly, formation of a SiC film on the rear surface 60b of the wafer 60 can be curbed. Therefore, deterioration in flatness of the rear surface 60b of the wafer 60 can be curbed. Accordingly, deterioration in flatness of the wafer 60 can be curbed. Other constitutions and the like of the susceptor 134 according to the present modification example are the same as other constitutions and the like of the susceptor 34 according to the embodiment described above.

As described above, in the present modification example, each of the plurality of recessed portions 137k opens on the support portion inner side surface 37d. Thus, according to the present modification example, a part of each of the recessed portions 137k is recessed downward from the inclined surface 37f. For this reason, even if the wafer 60 is thermally deformed into a shape of being warped downward during film formation, the rear surface 60b of the wafer 60 comes into contact with a part of the corner portion at the upper end of each of the recessed portions 137k positioned on the inclined surface 37f, that is, an inward part of the corner portion at the upper end of each of the recessed portions 137k in the radial direction. Thus, during film formation, if the wafer 60 tends to rotationally move with respect to the susceptor 134, the rear surface 60b of the wafer 60 is caught by the corner portion at the upper end of each of the recessed portions 137k. Accordingly, since a frictional force between the wafer 60 and the wafer support portion 137 can be increased, occurrence of wafer misalignment can be more favorably curbed. Therefore, deterioration in flatness of the wafer 60 can be curbed. In addition, thickness uniformity of the film formed on the wafer 60 can be improved.

In addition, according to the present modification example, similar to the embodiment described above, the wafer support portion 137 has the inclined surface 37f. Thus, even if the wafer 60 is thermally deformed into a shape of being warped downward during film formation, the rear surface 60b of the wafer 60 and the inclined surface 37f are likely to come into surface contact with each other. For this reason, a frictional force between the wafer 60 and the wafer support portion 137 can be increased. Therefore, since occurrence of wafer misalignment can be curbed during film formation, deterioration in flatness of the wafer 60 can be curbed, and thickness uniformity of the film formed on the wafer 60 can be improved.

### Second Modification Example

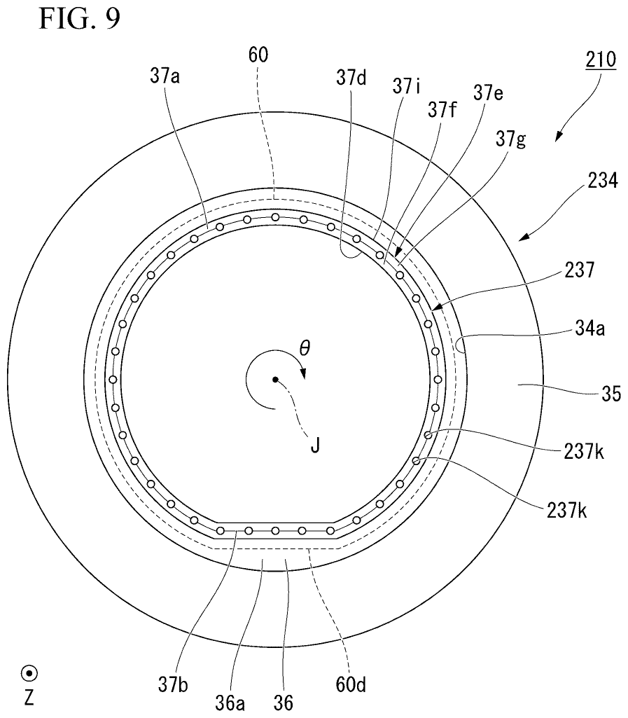

FIG. 9 is a top view showing a part of a vapor phase growth apparatus 210 according to the present modification example. In the following description, the same reference signs will be applied to constituent elements having the same form as those of the embodiment described above, and description thereof will be omitted.

In the present modification example, as shown in FIG. 9, each of a plurality of recessed portions 237k provided in a wafer support portion 237 has a circular shape when viewed in the vertical direction. In the present modification example, each of the recessed portions 237k does not open on either the support portion inner side surface 37d or the support portion outer side surface 37i. Thus, according to the present modification example, similar to the first modification example described above, during film formation, inflow of the gas G into the lower space S through each of the recessed portions 237k can be curbed. Accordingly, formation of a SiC film on the rear surface 60b of the wafer 60 can be curbed. Therefore, deterioration in flatness of the rear surface 60b of the wafer 60 can be curbed. Other constitutions and the like of a susceptor 234 according to the present modification example are the same as other constitutions and the like of the susceptor 34 according to the embodiment described above.

In the present modification example, a part of each of the recessed portions 237k is recessed downward from the inclined surface 37f. For this reason, even if the wafer 60 is thermally deformed into a shape of being warped downward during film formation, the rear surface 60b of the wafer 60 comes into contact with a part of the corner portion at the upper end of each of the recessed portions 237k positioned on the inclined surface 37f, that is, an inward part of the corner portion at the upper end of each of the recessed portions 237k in the radial direction. Thus, during film formation, if the wafer 60 tends to rotationally move with respect to the susceptor 234, the rear surface 60b of the wafer 60 is caught by the corner portion at the upper end of each of the recessed portions 237k. Accordingly, since a frictional force between the wafer 60 and the wafer support portion 237 can be increased, occurrence of wafer misalignment can be more favorably curbed. Therefore, deterioration in flatness of the wafer 60 can be curbed, and thickness uniformity of the film formed on the wafer 60 can be improved.

In addition, according to the present modification example, similar to the embodiment described above, the wafer support portion 237 has the inclined surface 37f. Thus, even if the wafer 60 is thermally deformed into a shape of being warped downward during film formation, the rear surface 60b of the wafer 60 and the inclined surface 37f are likely to come into surface contact with each other. For this reason, it is easy to curb decrease in the frictional force between the wafer 60 and the wafer support portion 237. Therefore, during film formation, occurrence of wafer misalignment such as rotational movement of the wafer 60 with respect to the susceptor 234 can be curbed. Accordingly, deterioration in flatness of the wafer 60 can be curbed, and thickness uniformity of the film formed on the wafer 60 can be improved.

According to the susceptors of the embodiment and the modification examples described above, the support surface has an inclined surface connected to the inner edge of the wafer support portion and positioned upward as the inclined surface approaches an outward side of the wafer support portion in a radial direction. Accordingly, occurrence of wafer misalignment during film formation can be curbed, and thickness uniformity of the film formed on the front surface of the wafer can be improved.

In addition, according to the susceptors of the embodiment and the modification examples described above, the wafer support portion has a plurality of recessed portions recessed downward from the support surface. Accordingly, during placement of placing a wafer on the susceptor and during film formation, the rear surface of the wafer and the corner portion at the upper end of each of the recessed portions can be brought into contact with each other. Thus, during placement and film formation, if the wafer tends to rotationally move with respect to the susceptor, the rear surface of the wafer is caught by the corner portion at the upper end of each of the recessed portions. Accordingly, a frictional force between the wafer and the wafer support portion can be increased. Therefore, during placement and film formation, occurrence of wafer misalignment can be more favorably curbed. For this reason, deterioration in flatness of the wafer can be curbed, and thickness uniformity of the film formed on the wafer can be more favorably improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form according to the embodiments described herein may be made without departing from the spirit of the inventions. The accompanying claims and their equivalents are intended to cover such forms or modifications as would fall within the scope and spirit of the inventions.

What is claimed is:

1. A vapor phase growth apparatus comprising:
a susceptor on which a wafer is to be placed; and
a drive portion for rotating the susceptor,
wherein the susceptor has a wafer support portion having annular shape and supporting the wafer,
the wafer support portion has a support surface supporting the wafer from below,
the support surface has an inclined surface connected to an inner edge of the wafer support portion, and a flat portion facing upward,
the inclined surface is positioned upward as the inclined surface approaches an outward side of the wafer support portion in a radial direction, and
the flat portion is connected to an outer end portion of the inclined surface in the radial direction.

2. The vapor phase growth apparatus according to claim 1,
wherein the inclined surface extends along a circumferential direction of the wafer support portion.

3. The vapor phase growth apparatus according to claim 1,
wherein the wafer support portion has a plurality of recessed portions recessed downward from the support surface, and
the plurality of recessed portions are disposed with an interval therebetween along a circumferential direction of the wafer support portion.

4. The vapor phase growth apparatus according to claim 3,
wherein at least one of the plurality of recessed portions opens on each of an inner side surface of the wafer support portion and an outer side surface of the wafer support portion.

5. The vapor phase growth apparatus according to claim 3,
wherein each of the plurality of recessed portions opens only on either an inner side surface of the wafer support portion or an outer side surface of the wafer support portion.

6. The vapor phase growth apparatus according to claim 5,
wherein each of the plurality of recessed portions opens on the inner side surface of the wafer support portion.

7. A vapor phase growth apparatus according to claim 1, further comprising:
a wafer guide having annular shape, surrounding an outer edge of the wafer, and disposed on the susceptor,
wherein a virtual straight line passing through an inner end portion of the inclined surface in the radial direction and an outer end portion of the inclined surface in the radial direction intersects an inner side surface of the wafer guide.

8. A vapor phase growth apparatus comprising:
a susceptor on which a wafer is to be placed; and
a drive portion for rotating the susceptor,
wherein the susceptor has a wafer support portion having annular shape and supporting the wafer,
the wafer support portion has a support surface supporting the wafer from below, and a plurality of recessed portions recessed downward from the support surface, and
the plurality of recessed portions are disposed with an interval therebetween along a circumferential direction of the wafer support portion.

9. The vapor phase growth apparatus according to claim 8,
wherein at least one of the plurality of recessed portions opens on each of an inner side surface of the wafer support portion and an outer side surface of the wafer support portion.

10. The vapor phase growth apparatus according to claim 8,
wherein each of the plurality of recessed portions opens only on either an inner side surface of the wafer support portion or an outer side surface of the wafer support portion.

11. The vapor phase growth apparatus according to claim 10,
wherein each of the plurality of recessed portions opens on the inner side surface of the wafer support portion.
